(19) United States
(12) Patent Application Publication
(10) Pub. No.: US 2026/0026029 A1
(43) Pub. Date: Jan. 22, 2026

(54) GaN DEVICE WITH GATE-CONNECTED FIELD PLATE, INTEGRATED GATE-TO-SOURCE CAPACITOR AND A GATE CONNECTED SHIELD LAYER

(71) Applicant: Navitas Semiconductor Limited, Dublin (IE)

(72) Inventor: Santosh Sharma, Austin, TX (US)

(73) Assignee: Navitas Semiconductor Limited, Dublin (IE)

(21) Appl. No.: 19/266,074

(22) Filed: Jul. 10, 2025

Related U.S. Application Data
(60) Provisional application No. 63/672,184, filed on Jul. 16, 2024.

(51) Int. Cl. H10D 30/47; H02M 3/158; H10D 30/01; H10D 62/10; H10D 62/824; H10D 64/00; H10D 64/23; H10D 84/00

(52) U.S. Cl. CPC H10D 30/475; H02M 3/1582; H10D 30/015; H10D 62/102; H10D 62/124; H10D 62/824; H10D 64/112; H10D 64/251; H10D 84/101

(57) ABSTRACT

A device is disclosed. The device includes a gallium nitride (GaN)-based substrate including a two-dimensional electron gas (2DEG) layer, a source region including a source electrode, a drain region separate from the source region, a gate region disposed between the source region and the drain region, the gate region including a P-type GaN layer and a gate electrode disposed on a top surface of the P-type GaN layer, wherein the gate electrode extends from a first edge to a second edge; and a field plate electrically coupled to the gate electrode at a junction. In one aspect, the field plate extends from the junction towards the source region, beyond the first edge, to a first distal end that is proximate the source electrode. In another aspect, the field plate extends from the junction towards the drain region, beyond the second edge, to a second distal end.

### CROSS REFERENCE TO RELATED APPLICATIONS

This application claims priority to U.S. provisional patent application No. 63/672,184, for “GaN DEVICE WITH GATE-CONNECTED FIELD PLATE AND INTEGRATED GATE-TO-SOURCE CAPACITOR AND WITH GATE CONNECTED SHIELD FIELD PLATE” filed on Jul. 16, 2024, which is hereby incorporated by reference in entirety for all purposes.

### FIELD

The described embodiments relate generally to semiconductor devices, and more particularly, the present embodiments relate to gallium nitride (GaN) based devices with gate connected shield field plate.

### BACKGROUND

In semiconductor technology, GaN is used to form various integrated circuit devices, such as high power field-effect transistors, metal insulator semiconductor field effect transistors (MISFETs), high frequency transistors, high power Schottky rectifiers, and high electron mobility transistors (HEMTs). These devices can be formed by growing epitaxial layers, which can be grown on silicon, silicon carbide, sapphire, gallium nitride, or other substrates. Often, devices are formed using a heteroepitaxial junction of AlGaN and GaN. This structure is known to form a high electron mobility two-dimensional electron gas (2DEG) at the junction. Sometimes additional layers are added to improve or modify the charge density and mobility of electrons in the 2DEG.

### SUMMARY

In some embodiments, a device is disclosed. The device includes a silicon layer: a gallium nitride (GaN)-based layer disposed on the silicon layer: a source region having a source electrode and disposed on the GaN-based layer: a drain region disposed on the GaN-based layer and separate from the source region: a gate region disposed between the source region and the drain region, the gate region including a P-type GaN layer having a first thickness and disposed on the GaN-based layer; and a dielectric layer disposed on the GaN-based layer and having a second thickness that is less the first thickness, where the dielectric layer is in contact with the P-type GaN layer.

In some embodiments, the device further includes a field plate disposed on the dielectric layer and positioned between the P-type GaN layer and the drain region, where the field plate is connected to the source electrode.

In some embodiments, the device further includes a shield layer extending from the P-type GaN layer towards the drain region and extending over at least a portion of the field plate.

In some embodiments, the dielectric layer is a first dielectric layer, and where the device further includes a second dielectric layer disposed between the field plate and the first dielectric layer.

In some embodiments, the device further includes a third dielectric layer disposed on the field plate.

In some embodiments, the device further includes a fourth dielectric layer disposed on the third dielectric layer.

In some embodiments, the shield layer extends over the third and fourth dielectric layers.

In some embodiments, a ratio of a sum of a thickness of the first dielectric layer, the field plate, the second dielectric layer, the third dielectric layer, and the fourth dielectric layer to the thickness of the first dielectric layer is between 1.05 and 15.

In some embodiments, a sum of a thickness of the first dielectric layer, the field plate, the second dielectric layer, the third dielectric layer and the fourth dielectric layer is between 10 and 5000 nm.

In some embodiments, a device is disclosed. The device includes a gallium nitride (GaN)-based substrate including a two-dimensional electron gas (2DEG) layer: a source region including a source electrode: a drain region separate from the source region; a gate region disposed between the source region and the drain region, the gate region including a P-type GaN layer and a gate electrode disposed on a top surface of the P-type GaN layer, where the gate electrode extends from a first edge to a second edge; and a field plate electrically coupled to the gate electrode at a junction, where the field plate extends from the junction towards the source region, beyond the first edge, to a first distal end that is proximate the source electrode, and where the field plate extends from the junction towards the drain region, beyond the second edge, to a second distal end.

In some embodiments, the first distal end overlaps the source electrode.

In some embodiments, the P-type GaN layer has a width defined between the first edge and the second edge, where the second distal end extends beyond the second edge by a distance greater than 20% of the width.

In some embodiments, the P-type GaN layer has a width defined between the first edge and the second edge, where the second distal end extends beyond the second edge by a distance greater than 30% of the width.

In some embodiments, the P-type GaN layer has a width defined between the first edge and the second edge, where the second distal end extends beyond the second edge by a distance greater than 50% of the width.

In some embodiments, a method of forming a device is disclosed. The method includes: providing a silicon layer; forming a gallium nitride (GaN)-based layer on the silicon layer; forming a source region on the GaN-based layer and having a source electrode; forming a drain region on the GaN-based layer and separate from the source region; forming a gate region between the source region and the drain region, the gate region including a P-type GaN layer having a first thickness and disposed on the GaN-based layer; and forming a dielectric layer disposed on the GaN-based layer and having a second thickness that is less the first thickness, where the dielectric layer is in contact with the P-type GaN layer.

In some embodiments, the method further includes forming a field plate disposed on the dielectric layer and positioned between the P-type GaN layer and the drain region, where the field plate is connected to the source electrode.

In some embodiments, the method further includes forming a shield layer extending from the P-type GaN layer towards the drain region and extending over at least a portion of the field plate.

In some embodiments, the dielectric layer is a first dielectric layer, and where the method further includes forming a second dielectric layer disposed between the field plate and the first dielectric layer.

In some embodiments, the method further includes forming a third dielectric layer disposed on the field plate.

In some embodiments, the method further includes forming a fourth dielectric layer disposed on the third dielectric layer.

### BRIEF DESCRIPTION OF THE DRAWINGS

A more detailed understanding of the one or more embodiments disclosed herein may be had from the following description, given by way of example in conjunction with the accompanying drawings, wherein like reference numerals in the figures indicate like elements, and wherein:

FIG. 1 is a schematic symbol for a GaN enhancement-mode n-channel transistor.

FIG. 2 is a cutaway side view of a GaN enhancement-mode n-channel transistor having a gate-connected field plate, an integrated gate-to-source capacitance Cgs, and an optional source-connected field plate, according to an embodiment.

FIG. 3 is a cutaway side view of the GaN enhancement-mode n-channel transistor of FIG. 2 in which the gate-connected field plate extends past an edge of the gate, according to an embodiment.

FIG. 4 is a cutaway isometric view of the integrated gate-to-source capacitance of the GaN transistors of FIGS. 2-3, according to an embodiment.

FIG. 5 is a cutaway side view of the GaN enhancement mode n-channel transistors of FIGS. 2-3 in which the gate-connected field plate extends over the source, according to an embodiment.

FIG. 6 is a cutaway isometric view of the integrated gate-to-source capacitance of the GaN transistor of FIG. 5, according to an embodiment.

FIG. 7 is a cutaway side view of the source conductive via and surrounding structure of FIG. 5, according to an embodiment.

FIG. 8 is a cutaway side view of a gate-connected-field-plate structure suitable for replacing the corresponding structure in the GaN transistors of FIGS. 2-3 and 5, according to an embodiment.

FIG. 9 is a cutaway side view of a source-connected-field-plate structure suitable for replacing the corresponding structure in the GaN transistors of FIGS. 2-3 and 5, according to an embodiment.

FIG. 10 is a schematic diagram of a buck-converter power supply that can incorporate one of the GaN transistors of FIG. 2, 3, or 5, according to an embodiment.

FIG. 11 illustrates a cross-sectional view of a GaN device with a gate connected shield field plate, according to some embodiments of the disclosure.

### DETAILED DESCRIPTION

In the following description, “approximate,” approximately,” “about,” and “substantially,” means that a quantity (e.g., a distance) can vary from a given value (e.g., 10 feet) by up to ±20% (e.g., ±20% of 10 feet=±2 feet, which means an “approximate” value of 10 feet can range from 10-2=8 feet to 10+2=12 feet), and means that a range a to b (e.g., of distance) can vary from up to (a−20%|b−a) to (b+20%|b−a) (e.g., an “approximate” range of 10 feet to 30 feet can range up to 6 feet to 34 feet).

Devices, structures and related techniques disclosed herein relate to GaN based devices with gate connected shield field plates. Gallium-Nitride (GaN) transistor (e.g., an n-channel enhancement-mode GaN transistor) can have one or more advantages over a comparable silicon transistor (e.g., an n-channel MOSFET), including faster switching speed, higher breakdown voltage, and reduced conduction losses (e.g., due to a lower value of Rds(on) for a given breakdown voltage). The GaN transistor can include a source region, a gate region and a drain region. The source region can include a source electrode, the gate region can include a gate electrode, and the drain region can include a drain electrode. In some embodiments, the gate region can include regions in the GaN transistor that are proximate the gate electrode and are under the influence of the gate electrode when a bias is applied to the gate electrode.

However, the gate of a GaN transistor can include a gate edge that, during operation of the transistor, can generate an electric field that may adversely affect the operation of the transistor (e.g., due to field crowding). For example, such an electric field can cause the gate edge to trap charges and become defective over time. To mitigate such an electric field, an embodiment of a GaN transistor may include a gate-connected field plate that extends towards the drain region, where the gate-connected field plate is disposed past an edge of the gate. In some embodiments, the gate-connected field plate may be disposed relatively close to the GaN-based substrate as compared to conventional field plates. In various embodiments, extending the gate-connected field plate over the gate edge can further mitigate the electric field.

Although such a gate-connected field plate may increase the gate-to-drain capacitance (Cgd) of the GaN transistor, an embodiment of the GaN transistor can include an integrated gate-to-source capacitance (Cgs) that increases the transistor's total Cgs, thereby decreasing the transistor's Cgd/Cgs ratio. By reducing the transistor's Cgd/Cgs ratio, the GaN transistor performance can improve, such as reducing the dv/dt sensitivity of the GaN transistor. Although one might consider increasing Cgs, and reducing Cgd/Cgs, by adding an external capacitor across the external gate and source nodes of the GaN transistor, adding an external capacitor can degrade the performance of the GaN transistor by adding parasitic components such as one or more parasitic inductances (e.g., the inductances of the capacitor leads or the traces formed on the circuit board to accommodate the external capacitor).

An embodiment of a semiconductor device, such as the above-described GaN enhancement mode transistor, can include a GaN buffer, an AlGaN barrier, a source terminal, a drain terminal, a gate terminal, and a field plate. The AlGaN barrier can be formed over the GaN buffer, where a two-dimensional electron gas (2DEG) layer can be formed. The source terminal can contact the GaN buffer and the AlGaN barrier, and the drain terminal can contact the GaN buffer and the AlGaN barrier in respective regions that are distal from the source. The gate terminal can be formed over a region of the AlGaN barrier between the source and the drain. A field plate can be formed over and in contact with, the gate terminal. In some embodiments, the gate-connected field plate can form an upper plate of an integrated gate-to-source capacitance, where the source terminal can form the lower plate. During operation, such a transistor can mitigate (e.g., reduce the magnitude of) a gate-edge electric field, as compared to a conventional GaN transistor, without significantly increasing the transistor's Cgd/Cgs ratio.

In various embodiments, a GaN device formed on a substrate may have a gate, a source and a drain region and may include a gate connected shield field plate that is coupled to a gate electrode in the gate region. The gate electrode may be formed across a gate P-type GaN layer in the gate region and the gate electrode may be in ohmic or rectifying (Schottky) contact with the gate P-type GaN layer. The gate connected shield field plate may be positioned between the gate region and the drain region and may be formed such that it covers dielectric layers disposed between the gate region and the drain region. In this way, the dielectric layers disposed between the gate region and the drain region can be protected by the gate connected field plate from being etched away during metal etching processes. The gate connected shield field plate may also protect a first nitride layer disposed on the substrate and may also protect a surface of the substrate during the metal etching processes. In this way, performance of the GaN device can be improved by preventing damage to the GaN substrate surface and preventing surface state formation that can cause dynamic Rdson issues in GaN devices.

In some embodiments, the gate P-type GaN layer may be thicker than the first nitride dielectric layer, thereby a first portion of the gate connected shield field plate may rise up at a starting location that is higher relative to the first nitride layer. In some embodiments, structures and techniques disclosed herein can enable a reduction of a thickness of the first nitride layer disposed on the substrate. In this way, an electric field at an edge of the gate P-type structure closer to the substrate can be reduced, thereby improving reliability of the GaN device. In some embodiments, the GaN device may include a source connected field plate that is disposed between the gate region and the drain region and is arranged to substantially reduce a gate-to-drain capacitance of the GaN device. The source-connected field plate can be arranged to provide a relatively smooth rise for a portion of the gate connected shield field plate that is disposed distal from the gate region and closer to the drain region. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

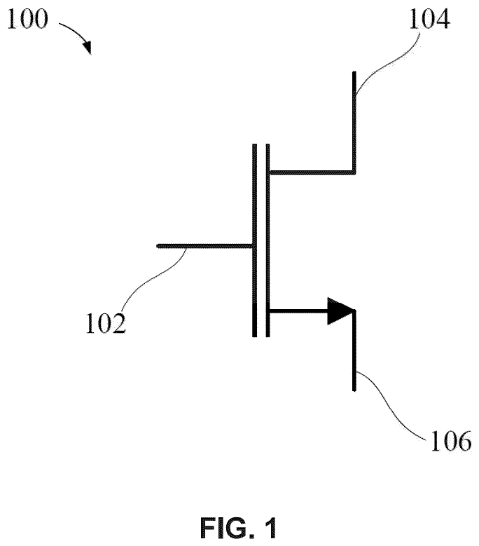

FIG. 1 shows a schematic symbol 100 for a GaN enhancement-mode transistor. The nodes 102 (G), 104 (D), and 106 (S) represent the gate terminal, drain terminal, and source terminal, respectively. A GaN enhancement-mode n-channel transistor may not have a body diode, however the GaN transistor can conduct current from the source terminal to its drain terminal.

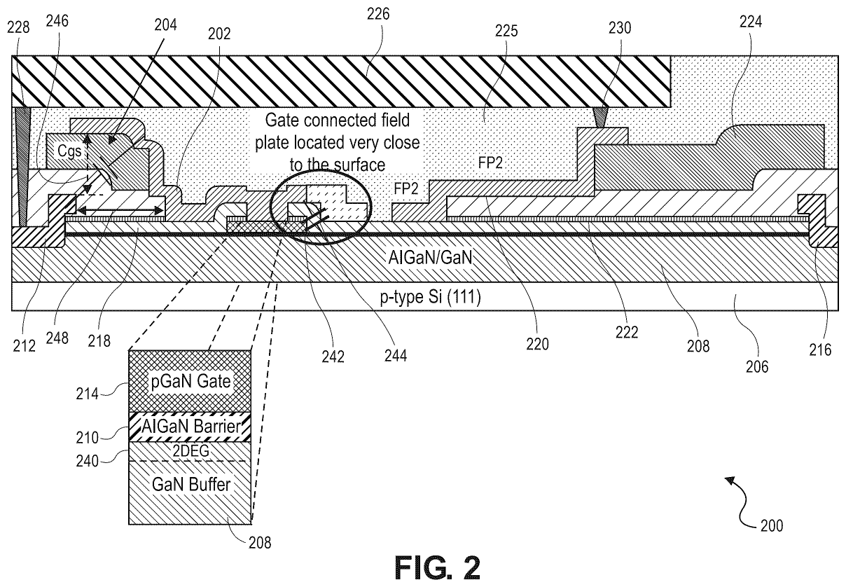

FIG. 2 illustrates a side view of a GaN enhancement-mode transistor 200, according to some embodiments. The GaN transistor can include a gate-connected field plate 202. The gate-connected field plate 202 can be arranged to provide a gate-edge-electric-field mitigation that can be relatively improved as compared to gate-edge-electric-field mitigation in current approaches. The gate-connected field plate 202 can include an integrated gate-to-source capacitance (Cgs) 204 that can be arranged to compensate for an increase in a gate-to-drain capacitance (Cgd) that may be caused by the gate-connected field plate. The gate-connected field plate 202 and the integrated Cgs 204 are described below in more detail.

The GaN transistor 200 can include a substrate 206, buffer 208, barrier 210, source 212, gate 214, drain 216, first dielectric layer 218, source-connected field plate 220, second dielectric layer 222, third dielectric layer 224, conductive member 226, and conductive vias 228 and 230. The substrate 206 can be a p-type silicon (Si) substrate having a (111) crystal orientation (sometimes called a (111) plane) at its upper surface to allow and to facilitate epitaxial growth of the buffer 208. The buffer 208 can include gallium nitride (GaN) 208, which is epitaxial grown over the substrate 206. The barrier 210 (represented by a black line in the non-blown-up portion of FIG. 2) can include aluminum gallium nitride (AlGaN), which is epitaxially grown over the buffer 208.

The source 212 (sometimes called an “ohmic source contact”) can be formed from a suitable conductive material such as a metal and contacts the buffer 208 and barrier 210. The gate 214 can include p-doped GaN (pGaN) and can be formed directly on (or otherwise over) the barrier 210. Like the source 212, the drain 216 (sometimes called an “ohmic drain contact”) can be formed from a suitable conductive material such as a metal and contacts the buffer 208 and barrier 210 in respective regions that are remote (laterally remote in the described embodiment) from the source.

The first dielectric layer 218 can be formed directly on (or otherwise over) the barrier 210 (but for the region where the gate 214 is disposed) and over the gate: the first dielectric layer may be formed directly on (or otherwise over) the gate, or there may be another dielectric, such as a portion of the second dielectric layer 222, formed between the gate and the first dielectric layer. For example, the first dielectric layer 218 can be formed from any suitable material, such as silicon nitride (SiN), and by any suitable process such as Plasma-Enhanced Chemical Vapor Deposition (PECVD), Low-Particle Tetraethyl Orthosilicate (LPTEOS), or Low-Pressure Chemical Vapor Deposition (LPCVD), and can have any suitable thickness such as <80 nanometers (nm), <85 nm, <120 nm, <150 nm, or ≤500 nm.

The source-connected field plate 220 can be formed from any suitable conductor, such as a metal, and can increase a drain-to-source breakdown voltage of the transistor 200 as compared to a breakdown voltage of a GaN transistor with no source-connected field plate 220. By forming and etching the second and third dielectric layers 222 and 224 before forming the source-connected field plate 220, one can form the source-connected field plate from a single layer of metal in a single manufacturing step. And the thickness of the source-connected field plate can range from <30 nm-400 nm.

The second dielectric layer 222 is formed directly on or otherwise over the first dielectric layer 218, can be formed from any suitable electrically insulating material, such as silicon dioxide (SiO₂), and by any suitable process, such as by PECVD, LPTEOS, or LPCVD, and can have any suitable thickness such as <160 nm, 100 nm-160 nm, or <100 nm. The third dielectric layer 224 can be formed directly on or otherwise over the second dielectric layer 222, can be formed from any suitable electrically insulating material, such as SiN, and by any suitable process, such as by PECVD, LPTEOS, or LPCVD, and can have any suitable thickness such as approximately 300 nm. A fourth dielectric layer 225 is formed over the third dielectric layer 224 and the field plates 202 and 220, can be formed from any suitable electrically insulating material, such as SiO2, and by any suitable process such as PECVD, LPTEOS, or LPCVD, and can have any suitable thickness.

The conductive member 226 can be formed directly on or over the fourth dielectric 225, and the conductive vias 228 and 230 are formed through the fourth dielectric such that the conductive members and conductive vias together couple the field plate 220 to the source 212. The conductive member 226 and the conductive vias 228 and 230 can be formed from any suitable conductive material (or the member and vias can be formed from different conductive materials) and can have any suitable dimensions. Coupling the field plate 220 to the source 212 can increase the drain-to-source breakdown voltage of the GaN transistor 200 as compared to a GaN transistor with no source-coupled field plate.

Still referring to FIG. 2, during operation of the GaN transistor 200, applying a positive voltage to the gate 214 and a positive voltage at the drain 216 relative to the source 212 causes the 2DEG region 240 (akin to a channel region in a MOSFET) to form at the interface between the buffer 208 and the barrier 210, thus allowing a conduction current (electron charge carriers) to flow between the source and the drain. By controllably varying the voltage at the gate 214, one can vary, in a controlled manner, the magnitude of current that flows in the 2DEG region 240 between the source 212 and the drain 216.

Without the gate-connected field plate 202, the gate 214 may generate a problematic electric field at a drain-facing gate edge 242. That is, the gate 214 may generate at the edge 242, an electric field that adversely affects, i.e., degrades the operating performance of the GaN transistor 200. For example, the edge 242 may be prone to defects and charge trapping because, e.g., the edge forms part of a three-dimensional upper corner of the gate 214, and, due to the gate-barrier transition, the edge also forms part of a three-dimensional bottom corner that is passivated. Because these corners are relatively sharp, electric-field crowding may occur at the corners, thus making it difficult to control the electric field at the gate edge 242 difficult. That is, the electric-field crowding may make it difficult to attenuate, shape, or otherwise mitigate the gate-edge electric field such that it may cause degradation of the operating performance of the GaN transistor 200.

In the illustrated embodiment, the gate-connected field plate 202 is arranged to mitigate the electric fields at the gate edge 242, thereby reducing or eliminating the degradation that these gate-edge electric fields otherwise may cause. Furthermore, because the first dielectric layer 218 is relatively thin, the gate-connected field plate 202 can be relatively close (e.g., 2-100 nm), to the AlGaN barrier 210, thus potentially causing an increase in the gate-to-drain capacitance 244, Cgd, as compared to the Cgd of a conventional enhancement-mode GaN transistor. Such an uncompensated increase in Cgd can increase the Cgd/Cgs ratio of the GaN transistor 200, thereby increasing the drain dv/dt and decrease the noise-immunity of the GaN transistor as compared to a conventional GaN transistor.

To compensate for the increase in Cgd by decreasing the Cgd/Cgs ratio to a suitable value, the GaN transistor 200 can include the integrated capacitance Cgs 204, that can increase the total value of Cgs as compared to the Cgs of a conventional GaN transistor.

The integrated Cgs 204 can be formed by the gate-connected field plate 202 (one plate/electrode of the integrated Cgs), the source 212 (the other plate/electrode of the integrated Cgs), and the portions of the second and third dielectric layers 222 and 224 that are between the gate-connected field plate and the source. For example, a vertical distance 246 between the gate-connected field plate 202 and the source 212 can be in an approximate range of 300 nm to 500 nm, and a horizontal distance 248 between the gate-connected field plate and the source can be in an approximately range of 100 nm to 5 μm. The integrated Cgs 204 can have various value ranges and the ratio Cgs/Cgd can have various value ranges.

Still referring to FIG. 2, alternate embodiments of the GaN transistor 200 are contemplated. For example, although the first, second, and third dielectric layers 218, 222, and 224 are described as being a nitride, and an oxide, and a nitride, respectively (N—O—N), these layers can be formed from other materials such as an oxide, a nitride, and an oxide (O—N—O). Furthermore, although the first dielectric layer 218 is described as being formed directly on the AlGaN barrier 210, a layer of another dielectric (e.g., aluminum oxide (AlO₂) or aluminum nitride (AlN)) can be formed over, or directly on, the AlGaN buffer by atomic-layer deposition (ALD), and the first dielectric layer 218 can be formed over, or directly on, the ALD dielectric layer. For example, the ALD dielectric layer can have a thickness in an approximate range of 2 nm-10 nm.

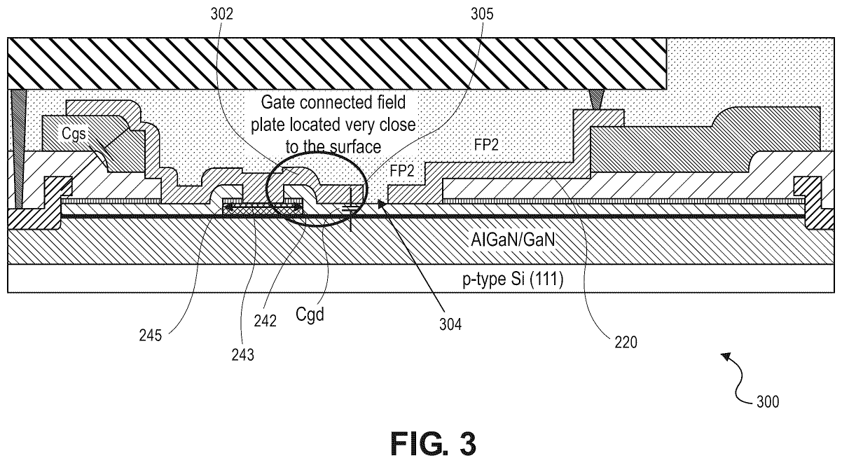

FIG. 3 is a cutaway side view of a GaN n-channel enhancement-mode transistor 300, where like numbers reference items common to FIGS. 2-3. The GaN transistor 300 is similar to the GaN transistor 200 of FIG. 2 except that the transistor 300 includes a gate-connected field plate 302 that extends over and past the gate edge 242 by, according to an embodiment. The level of gate-edge-electric-field mitigation that the field plate 302 can provide at the gate edge 242 can be greater than the level of gate-edge-electric-field mitigation that the field plate 202 of FIG. 2 provides for the GaN transistor 200 of FIG. 2. The gate-connected field plate 302 may not extend so far past the gate edge 242 as to contact the source-connected field plate 220. Instead, the GaN transistor 300 can include a gap 304 between the field plates 302 and 220 that can have a suitable value. In some embodiments, the P-type GaN layer has a width 243 that is defined between edge 245 and edge 242. An edge 305 of the field plate 302 can extend beyond the edge 242 by a distance greater than 20% of the width 243. In some embodiments, the edge 305 of the field plate 302 can extend beyond the edge 242 by a distance greater than 30% of the width 243, and in alternate embodiments, it can extend by 30% of the width 243.

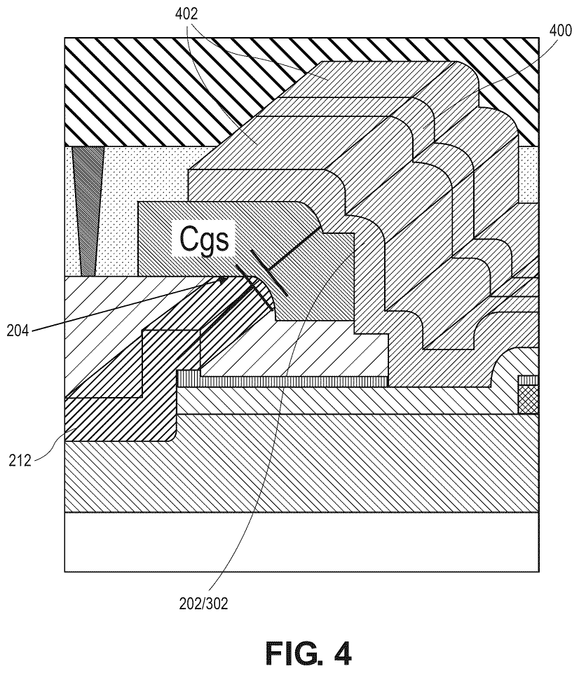

FIG. 4 is a cutaway isometric view of the integrated gate-to-source capacitance 204 of the GaN transistor 200 of FIG. 2 and the GaN transistor 300 of FIG. 3, according to an embodiment. One can adjust the depth (in a dimension normal to the pages of FIGS. 2-3) of the gate-connected field plate 202/302 to adjust the capacitance of Cgs 204 by adjusting the area of the gate-connected field plate adjacent to the source 212. Furthermore, one can adjust the area of the gate-connected field plate 202/302 with a finer resolution by segmenting the field plate with one or more dielectric regions 400. The resulting segments 402 of the field plate 202/302 can be of uniform or non-uniform depth (width), and the dielectric regions 400 can be of uniform or non-uniform depth (width). And the source 212 can have a depth (in a dimension normal to the pages of FIGS. 2-3) that is at least as deep as the gate-connected field plate 202/302 (the source typically is not segmented).

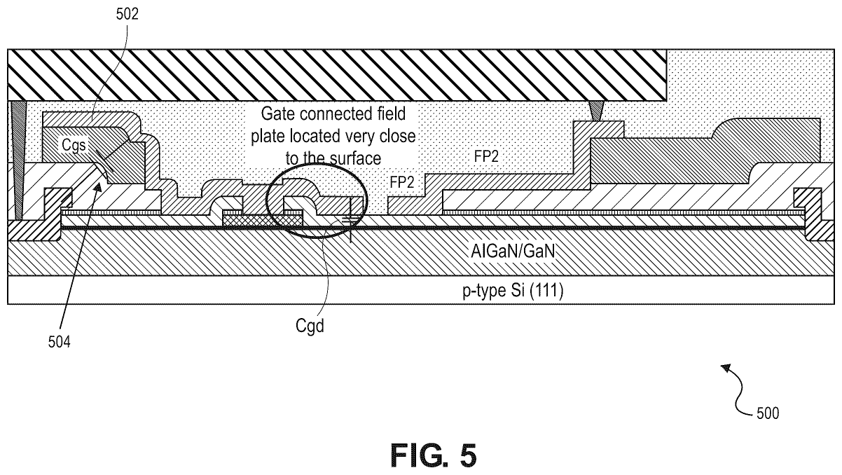

FIG. 5 is a cutaway side view of a GaN n-channel enhancement-mode transistor 500, where like numbers reference components common to FIGS. 2-4. The GaN transistor 500 is similar to the GaN transistor 300 of FIG. 3 except that the transistor 500 includes a gate-connected field plate 502 that extends further over the source 212 than the gate-connected field plate 302 of FIG. 3, according to an embodiment. The field plate 502 extending further over the source 212 can increase the area (A) of the effective top plate of the gate-to-source capacitance, Cgs, 504, and, therefore, can increase the capacitance of Cgs (C(apacitance)=ϵ·A/d) and reduce the ratio Cgd/Cgs as compared to the Cgs 204 and the ratio Cgd/Cgs of the transistors 200 and 300 of FIGS. 2-3.

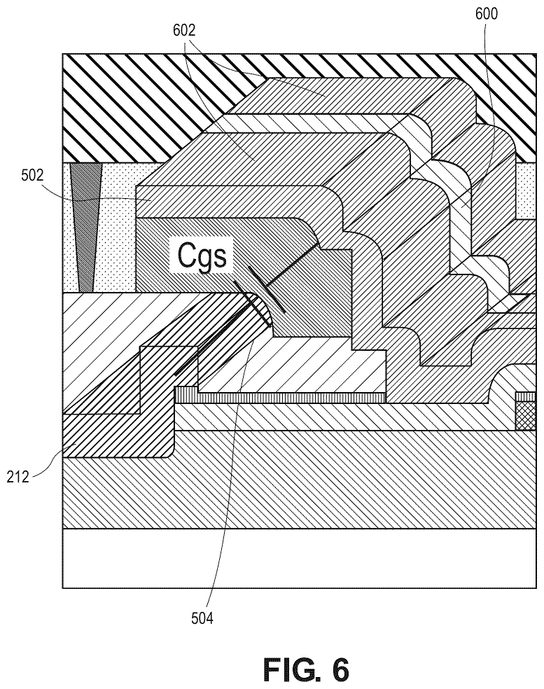

FIG. 6 is a cutaway isometric view of the integrated gate-to-source capacitance, Cgs, 504 of the GaN transistor 500 of FIG. 5, according to an embodiment. One can adjust the depth (in a dimension normal to the page of FIG. 5) of the gate-connected field plate 502 to adjust the capacitance of Cgs 504 by adjusting the area of the gate-connected field plate adjacent to the source 212. Furthermore, one can adjust the area of the gate-connected field plate 502 with a finer resolution by segmenting the field plate with one or more dielectric regions 600. The resulting segments 602 of the field plate 502 can be of uniform or non-uniform depth (width), and the dielectric regions 600 can be of uniform or non-uniform depth (width). And the source 212 can have a depth (in a dimension normal to the page of FIG. 5) that is at least as deep as the gate-connected field plate 502 (the source 212 typically is not segmented).

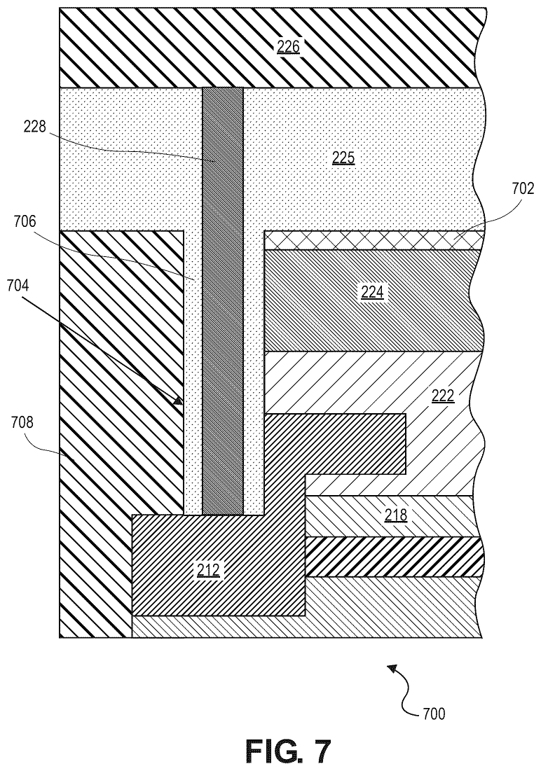

FIG. 7 is a cutaway side view of the source conductive via 228 and surrounding structure 700 of the GaN transistor 500 of FIGS. 5-6, according to an embodiment. Possible advantages of the structure 700 include that the relative thinness the gate-connected field plate 702 (can be similar to the gate-connected field plate 502 of FIG. 5) in the region of the conductive via 228 can be suitable for a source-contact etch—a thicker metal is typically not suitable for a contact etch—and that the relative short lateral distance between the gate-connected field plate and the conductive via can increase the capacitance of Cgs 504 significantly higher than what it would be without this relatively short lateral distance between the field plate and the conductive via.

In addition to the gate-connected field plate 702, GaN buffer 208, AlGaN barrier 210, source 212, first dielectric layer 218, second dielectric layer 222, third dielectric layer 224, fourth dielectric layer 225, and conductive member 226, the via-surrounding structure 700 includes a trench 704 filled with a dielectric spacer or liner 706, and another region 708. For example, the field plate 702 can have a thickness as low as 30 nm (at least in the region of the structure 700), the trench 704 can be formed self-aligned to the corresponding opening formed in the field plate 702 and the depth of the trench can be 1 μm or less, the liner 706 can be formed form a dielectric such as SiO₂ or SiN and have a thickness of suitable value and the other region 708 may be formed by one, or a combination, of the dielectric layers 222 and 224.

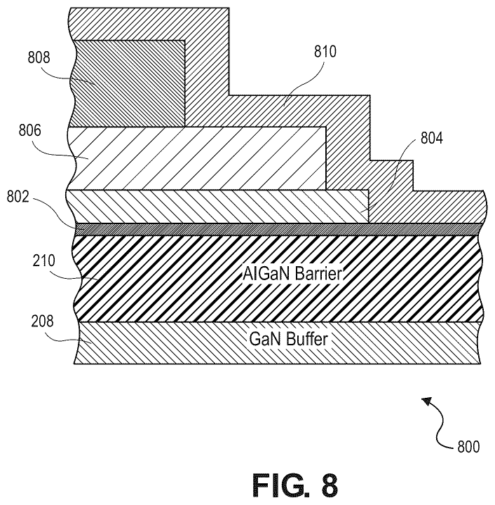

FIG. 8 is a cutaway side view of an alternative dielectric and gate-connected-field-plate structure 800 that can be located between the source 212 and the gate 214 of the transistors 200, 300, and 500 of FIGS. 2-6, according to an embodiment. One way in which the structure 800 differs from the structure in FIGS. 2-6 is that the structure 800 includes four dielectric layers 802, 804, 806, and 808 beneath a gate-connected field plate 810 instead of three dielectric layers such as in FIGS. 2-6 (dielectric layers 218, 222, and 224 beneath the gate-connected field plate 202/302/502).

The first dielectric layer 802 is disposed over (e.g., directly on) the AlGaN barrier 210. The layer 802 can be formed by, for example, atomic-layer deposition (ALD), can be formed from any suitable dielectric such as AlO2 or AlN, and can have a thickness of approximately 2-10 nm. The second dielectric layer 804 is disposed over (e.g., directly on) the first dielectric layer 802. The layer 804 can be formed by, for example, PECVD, LPTEOS, or LPCVD, can be formed from any suitable dielectric such as SiN, and can have a thickness of approximately 80 nm. The third dielectric layer 806 is disposed over (e.g., directly on) the second dielectric layer 804. The layer 806 can be formed by, for example, PECVD, LPTEOS, or LPCVD, can be formed from any suitable dielectric such as SiO₂, and can have a thickness of approximately 100 nm-160 nm. The fourth dielectric layer 808 is disposed over (e.g., directly on) the third dielectric layer 806. The layer 808 can be formed by, for example, PECVD, LPTEOS, or LPCVD, can be formed from any suitable dielectric such as SiN, and can have a thickness of approximately 300 nm.

After the layers 802-808 are etched to form the dielectric portion of the structure 800, the gate-connected field plate 810 is formed over the layers 802-808, for example as a single metal layer in a single formation (e.g., deposition) step. Advantages of the structure 800 include that because consecutive ones of the dielectric layers 802-808 can be made from different dielectric materials, they can facilitate the etching processes because each lower dielectric layer can act as an etch stop during the etching of the immediately higher dielectric layer (an ALD layer such as the layer 802 is typically a good etch stop for an immediately above layer that is made from any dielectric material). For example, the layer 804 can act as an etch stop during the etching of layer 806. Another advantage of the structure 800 is that between the source 212 and the gate 214, the gate-connected field plate 810 can be closer to the AlGaN Barrier 210 (e.g., can be just 2 nm-10 nm away from the AlGaN Barrier) than in a structure where the dielectric layer 802 is omitted, and, in an embodiment, can be as close the Barrier 210 as the gate-connected field plate 810 is between the gate and the drain 216.

Alternate embodiments of the structure 800 are contemplated. For example, although the dielectric layers 808, 806, and 804 are described as being a nitride (N)—oxide (O)—nitride (N), these layers can be an O—N—O.

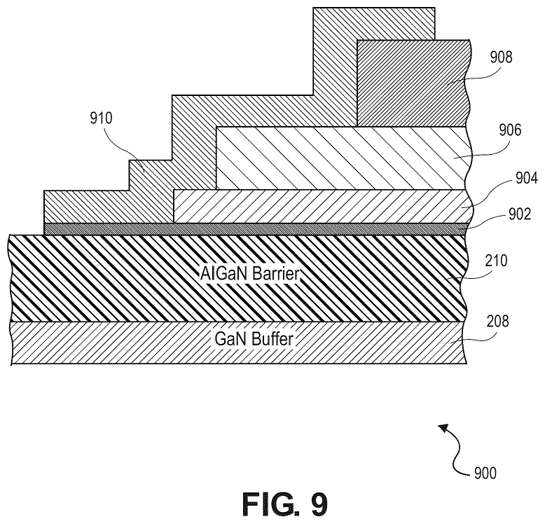

FIG. 9 is a cutaway side view of an alternative dielectric and source-connected-field-plate structure 900 that can be located between the gate 214 and the drain 216 of the GaN transistors 300, 300, and 500 of FIGS. 2-6, according to an embodiment. The structure 900 can be similar to the structure 800 of FIG. 8. One way in which the structure 900 differs from the structure beneath and including the source-connected field plate 220 in FIGS. 2-6 is that the structure 900 includes four dielectric layers 902, 904, 906, and 908 beneath a source-connected field plate 910 instead of three dielectric layers such as in FIGS. 2-6 (dielectric layers 218, 222, and 224 beneath the source-connected field plate 220).

The first dielectric layer 902 is disposed over (e.g., directly on) the AlGaN barrier 210. The layer 902 can be formed by, for example, atomic-layer deposition (ALD), can be formed from any suitable dielectric such as AlO₂ or AlN, and can have a thickness of approximately 2-10 nm. The second dielectric layer 904 is disposed over (e.g., directly on) the first dielectric layer 902. The layer 904 can be formed by, for example, PECVD, LPTEOS, or LPCVD, can be formed from any suitable dielectric such as SiN, and can have a thickness of approximately 80 nm. The third dielectric layer 906 is disposed over (e.g., directly on) the second dielectric layer 904. The layer 906 can be formed by, for example, PECVD, LPTEOS, or LPCVD, can be formed from any suitable dielectric such as SiO₂, and can have a thickness of approximately 100 nm-160 nm. The fourth dielectric layer 908 is disposed over (e.g., directly on) the third dielectric layer 906. The layer 908 can be formed by, for example, PECVD, LPTEOS, or LPCVD, can be formed from any suitable dielectric such as SiN, and can have a thickness of approximately 300 nm.

After the layers 902-908 are etched to form the dielectric portion of the structure 900, a source-connected field plate 910 is formed over the layers 902-908, for example as a single metal layer in a single step. Advantages of the structure 900 include that because consecutive ones of the dielectric layers 902-908 can be made from different dielectric materials, they can facilitate the etching processes because each lower dielectric layer can act as an etch stop during the etching of the immediately higher dielectric layer (an ALD layer, such as the layer 902, is typically a good etch stop for an immediately above layer that is made from any dielectric material). For example, the layer 904 can act as an etch stop during the etching of layer 906. Another advantage of the structure 900 is that the source-connected field plate 910 can be closer to the AlGaN Barrier 210 (e.g., can be just 2 nm-10 nm away from the AlGaN Barrier) than in a structure where the dielectric layer 902 is omitted.

Alternate embodiments of the structure 900 are contemplated. For example, although the dielectric layers 908, 906, and 904 are described as being a nitride (N)—oxide (O)—nitride (N), these layers can be an O—N—O.

Furthermore, referring to FIGS. 8-9, each of the pairs of layers 802-902, 804-904, 806-906, and 808-908, and the gate-connected field plate 810 and source-connected field plate 910, can be formed simultaneously.

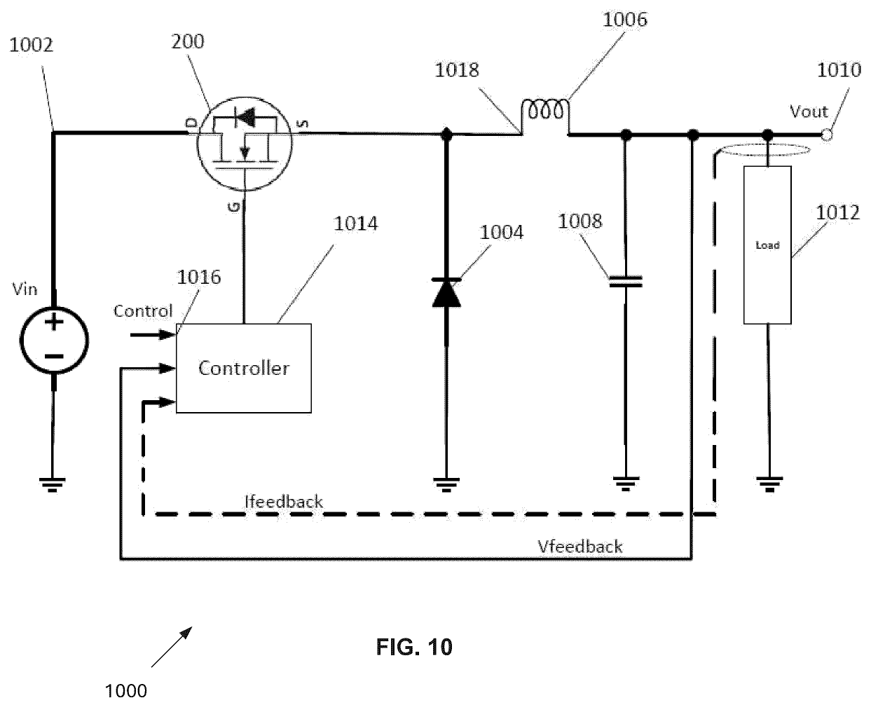

FIG. 10 is a schematic diagram of a power converter 1000 that can incorporate one of the enhancement-mode GaN n-channel transistors 200, 300, or 500 of FIGS. 2-3 and 5, according to an embodiment (for clarity, the buck converter is described as incorporating a single GaN enhancement-mode n-channel transistor 200, it being understood that the operation of the buck converter is comparable if incorporating a single GaN transistor 300 or 500). In some embodiments, the power supply can be a buck converter.

In addition to the GaN transistor 200, the power converter 1000 includes a voltage-input node 1002 configured for receiving an input voltage Vin, a diode or other unidirectional device 1004, at least one inductor 1006, a filter capacitor 1008, voltage-output node 1010 configured for providing a regulated output voltage Vout to a load 1012, and a controller 1014 configured for driving (e.g., switching) the GaN transistor.

In operation, at a control node 1016, the controller 1014 receives an analog or digital control signal that configures the controller to set Vout to a particular value, for example 1.10 Volts (V). During a first part of a switching cycle, the controller 1014 drives the transistor 200 to a conducting, or “on,” state. In response to the transistor 200 being “on,” and assuming that the voltage drop across the drain-source junction of the transistor is low enough to be negligible for purposes of this description, the transistor effectively couples the input voltage Vin to a node 1018 of the inductor 1006. Because Vin (e.g., 5.0 V) is higher than Vout, an increasing (ramping) current flows from the source(S) of the transistor 200, through the inductor 1006, and into both the capacitor 1008 and the load 1012, where the slope of the current increase is (Vin−Vout)/L, where L is the inductance of the inductor.

At some point after the controller 1014 turns the transistor 200 “on,” the increasing current flowing out from the inductor 1006 exceeds the current flowing into the load 1012. At this point, some of the current from the inductor flows into the filter capacitor 1008, thus increasing the charge on the capacitor and causing the voltage, Vout, across the capacitor to begin increasing in a ramping fashion. (this increasing and decreasing (described below) of Vout is often called the “output ripple voltage” or something similar).

Vout, or a derivative thereof, is fed back to the controller 1014 as feedback voltage Vfeedback. In response to Vfeedback exceeding a threshold voltage set by the control signal, the controller 1014 drives the transistor 200 into a nonconducting, or “off,” state in which the transistor sources negligible current to the inductor 1006.

In response to the turn “off” of the transistor 200, a decreasing (e.g., ramping down) current (sometimes called a “circulating current”) flows through the diode 1004, the inductor 1006 and into the capacitor 1008 and the load 1012. In response to this ramping-down inductor current becoming less than the current being drawn by the load 1012, the capacitor 1008 sources the difference between the inductor current and the load current, and Vout begins to ramp downward. In response to Vout, and thus Vfeedback, becoming less than the threshold voltage set by the control signal, the controller 1014 turns the transistor 200 “on” again, and the above-described switching cycle repeats.

The controller 1014 also can employ optional feedback Ifeedback of the current through the inductor 1006 (Ifeedback can be a voltage or a current) in addition to the voltage feedback Vfeedback. The controller 1014 turns the transistor 200 “on” and “off” in response to both Ifeedback and Vfeedback. Using current feedback can allow the controller 1014 to respond more rapidly to a load transient than voltage feedback alone. Still referring to FIG. 10, alternate embodiments of the power converter 1000 are contemplated. For example, instead of being a buck converter having the single-phase topology described, the power converter 1000 may be a buck converter having a multi-phase topology in which the buck converter incorporates multiple GaN transistors and multiple inductors. In some embodiments, the power converter 1000 can be another type of power supply, such as a boost converter, buck-boost converter, or flyback converter.

Referring to FIGS. 2, 3, 5, and 10, although described as being incorporated in a power converter 1000, other electronic circuits and systems can incorporate one or more of the GaN transistors. Furthermore, although described as being an n-channel transistor, one can form a counterpart GaN enhancement-mode p-channel transistor using the known principle of duality.

GaN Device with Gate Connected Shield Layer

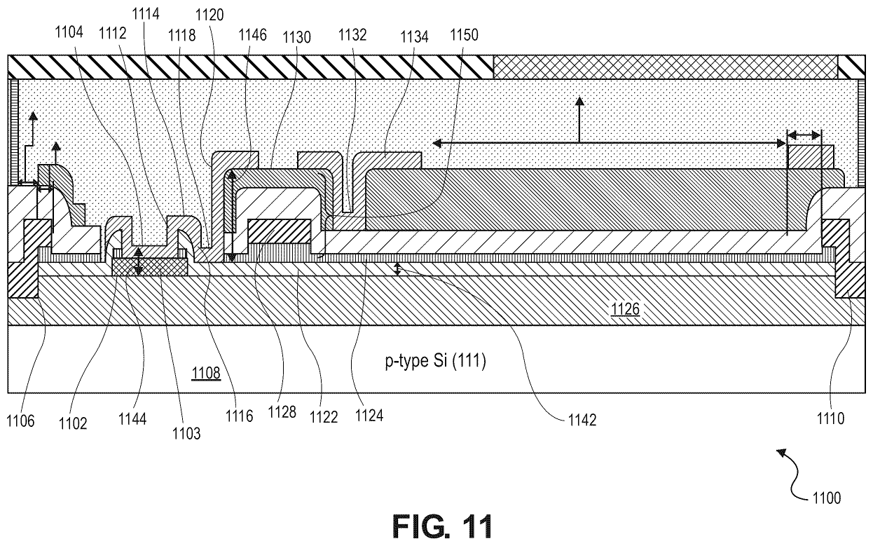

FIG. 11 illustrates a cross-sectional view of a GaN device with a gate connected shield field plate, according to some embodiments of the disclosure. In the illustrated embodiment, the GaN device 1100 can include a gate structure 1102 having a P-type GaN layer 1103 and a gate electrode 1104, a source electrode 1106, and a drain electrode 1110. The GaN device 1100 can be disposed on a semiconductor substrate 1108. In some embodiments, the semiconductor substrate 1108 can be silicon. A GaN-based layer 1126 may be formed on the substrate 1108. The GaN-based layer 1126 may include a transition structure formed over the semiconductor substrate 1108, a GaN region formed over transition structure, and AlGaN layer formed over GaN region. A two-dimensional electron gas (2DEG) may be formed at the interface of the AlGaN and GaN. An ohmic metal layer can be formed in the source region. In the drain region, another ohmic metal layer can be formed. A first nitride-based dielectric layer 1122 may be disposed on the GaN-based layer 1126. In some embodiments, the first nitride-based dielectric layer 1122 may be formed from, for example, silicon nitride, silicon oxide, aluminum oxide, aluminum nitride and/or ALD. A first silicon oxide-based dielectric layer 1124 may be disposed on the first nitride-based dielectric layer 1122. In some embodiments where layer 1122 is silicon oxide based, layer 1124 may be nitride based.

A gate connected shield field plate may be coupled to the gate electrode 1104 and may include a first portion 1112, a second portion 1114, a third portion 1116, a fourth portion 1118 and a fifth portion 1120. In some embodiments, the gate connected shield field plate may be referred to as a shield layer. The first portion 1112 may be disposed proximal to the gate electrode 1104, where the first portion rises with respect to the gate electrode 1104. The second portion may be disposed parallel to the surface of the nitride-based layer 1126. The third portion 1116 may go down from the second portion 1114 towards the surface of the nitride-based layer 1126. The fourth portion that may be positioned towards the drain terminal region 1110 and may be disposed on the first nitride-based dielectric layer 1122 and may be parallel to the surface of the nitride-based layer 1126.

In some embodiments, a thickness of the first nitride-based dielectric layer 1122 may be less than a thickness of the P-type GaN layer 1103, thereby the fourth portion may be disposed relatively closer to the surface of the nitride-based layer 1126 than the gate electrode 1104. The fifth portion 1120 may rise away from the surface of the nitride-based layer 1126 and may be disposed over a pedestal 1150. The pedestal 1150 may include a source-connected field plate 1128, a second nitride-based layer 1130, a second silicon oxide-based layer 1140, and the first silicon oxide-based dielectric layer 1124. The source-connected field plate 1128 may be arranged to provide a relatively smooth rise for the fifth portion 1120. In some embodiments, the pedestal may not include a source-connected field plate. Other alternative semiconductor layers can also be used and are within the scope of this disclosure. For example, in some embodiments the pedestal 1150 may include ALD, aluminum oxide and/or oxide-nitride-oxide layers.

The substrate 1108 may be formed of materials such as silicon (Si), silicon carbide (SiC), bulk III-Nitride material, sapphire, or any other suitable material. Furthermore, substrate 1108 may be single crystal, polycrystalline, or a composite substrate. As used herein, a silicon, or Si, substrate may refer to any substrate that includes silicon. Examples of suitable Si substrates can include substrates that are composed entirely of Si (e.g., bulk Si wafers), silicon-on-insulator (SOI) substrates, silicon-on-sapphire substrates (SOS), and separation by implantation of oxygen (SIMOX) process substrates. Suitable Si substrates can also include composite substrates that have a silicon wafer bonded to another material such as diamond, aluminum nitride (AlN), or other polycrystalline materials.

In some embodiments, a thickness 1144 of the gate structure 1102 can be, for example, between 50 nm and 100 nm. In some embodiments, the thickness 1144 can between 70 nm and 90 nm while in other embodiments the thickness can be between 30 nm and 200 nm and in various embodiments the thickness can be between 10 and 500 nm. In some embodiments, a thickness 1142 of the first nitride-based dielectric layer 1122 can be, for example, between 5 nm and 20 nm. In some embodiments, the thickness 1142 can between 9 nm and 11 nm while in other embodiments the thickness can be between 1 nm and 50 nm. In some embodiments, a thickness 1146 of the pedestal 1150 can be, for example, between 50 nm and 2000 nm. In some embodiments, the thickness 1146 can between 90 nm and 1100 nm while in other embodiments the thickness can be between 30 nm and 1200 nm and in various embodiments the thickness can be between 10 and 5000 nm. The above thicknesses may also be used for alternative semiconductors layers as described previously.

In some embodiments, a ratio of a distance between the thickness 1146 of the pedestal 1150 to the thickness 1142 of the first nitride-based dielectric layer 1122 can be between 1.1 and 100, while in other embodiments the ratio can be between 1.05 and 15, and in various embodiments the ratio can be between 1.01 and 10.0. As appreciated by one of ordinary skill in the art having the benefit of this disclosure, the thicknesses of the dielectric layers and the pedestal, and the ratio of a distance between the thickness 1146 of the pedestal 1150 to the thickness 1142 of the first nitride-based dielectric layer 1122 can be set to any suitable value. The above thicknesses may also be used for alternative semiconductors layers (e.g., ALD, aluminum oxide, or aluminum nitride) as described previously. Further, as appreciated by one of ordinary skill in the art, disclosed field plate structures can have one or more pedestals, different sized pedestals and other characteristics that can be different than those described here. Moreover, as appreciated by one of ordinary skill in the art, the dielectric layer can be constructed from one or more dielectric layers.

The GaN device 1100 can further include a third field plate 1132 and a fourth field plate 1134. In this way, the GaN device 1100 can be arranged to optimize the electric fields and improve reliability and performance of the GaN device. The third field plate 1132 and the fourth field plate 1134 can also be coupled to the source terminal. The third field plate can start from top of the pedestal and goes down and then goes back up.

Although structures and techniques disclosed are described and illustrated herein with respect to some particular configuration of GaN device with gate connected shield field plate, embodiments of the disclosure are suitable for use with other configurations of semiconductor devices. For example, gate-connected shield field plates may be used in silicon and/or silicon carbide-based transistors to shield the underlying dielectric layers from etching processes and to improve transistor performance by reducing the gate to drain capacitance. Gate-connected shield field plates can be used in lateral semiconductor transistors as well as vertical semiconductor transistors.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “and/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

One of ordinary skill in the art will appreciate that other modifications to the apparatuses and methods of the present disclosure may be made for implementing various applications of the methods and systems for enhanced area getter architecture for a wafer-level vacuum packaged uncooled focal plane array without departing from the scope of the present disclosure.

The examples and embodiments described herein are for illustrative purposes only. Various modifications or changes in light thereof will be apparent to persons skilled in the art. These are to be included within the spirit and purview of this application, and the scope of the appended claims which follow.

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated. Moreover, one or more components of a described apparatus or system may have been omitted from the description for clarity or another reason. In addition, one or more components of a described device, apparatus, or system that have been included in the description may be omitted from the device, apparatus, or system. Furthermore, one or more steps, acts, or other items of a described method or procedure may have been omitted from the description for clarity or another reason. Moreover, one or more steps, acts, or other items of a described method or procedure that have been included in the description may be omitted from the method or procedure. And although features and elements are described above in particular combinations, one of ordinary skill in the art will appreciate that each feature or element can be used alone or in any combination with the other features and elements.

What is claimed is:

1. A device comprising:
a silicon layer;
a gallium nitride (GaN)-based layer disposed on the silicon layer;
a source region having a source electrode and disposed on the GaN-based layer;
a drain region disposed on the GaN-based layer and separate from the source region;
a gate region disposed between the source region and the drain region, the gate region including a P-type GaN layer having a first thickness and disposed on the GaN-based layer; and
a dielectric layer disposed on the GaN-based layer and having a second thickness that is less the first thickness, wherein the dielectric layer is in contact with the P-type GaN layer.

2. The device of claim 1, further comprising a field plate disposed on the dielectric layer and positioned between the P-type GaN layer and the drain region, wherein the field plate is connected to the source electrode.

3. The device of claim 2, further comprising a shield layer extending from the P-type GaN layer towards the drain region and extending over at least a portion of the field plate.

4. The device of claim 3, wherein the dielectric layer is a first dielectric layer, and wherein the device further comprises a second dielectric layer disposed between the field plate and the first dielectric layer.

5. The device of claim 4, wherein the device further comprises a third dielectric layer disposed on the field plate.

6. The device of claim 5, wherein the device further comprises a fourth dielectric layer disposed on the third dielectric layer.

7. The device of claim 6, wherein the shield layer extends over the third and fourth dielectric layers.

8. The device of claim 6, wherein a ratio of a sum of a thickness of the first dielectric layer, the field plate, the second dielectric layer, the third dielectric layer, and the fourth dielectric layer to the thickness of the first dielectric layer is between 1.05 and 15.

9. The device of claim 6, wherein a sum of a thickness of the first dielectric layer, the field plate, the second dielectric layer, the third dielectric layer and the fourth dielectric layer is between 10 and 5000 nm.

10. A device comprising:
a gallium nitride (GaN)-based substrate including a two-dimensional electron gas (2DEG) layer;
a source region including a source electrode;
a drain region separate from the source region;
a gate region disposed between the source region and the drain region, the gate region including a P-type GaN layer and a gate electrode disposed on a top surface of the P-type GaN layer, wherein the gate electrode extends from a first edge to a second edge; and
a field plate electrically coupled to the gate electrode at a junction, wherein the field plate extends from the junction towards the source region, beyond the first edge, to a first distal end that is proximate the source electrode, and wherein the field plate extends from the junction towards the drain region, beyond the second edge, to a second distal end.

11. The device of claim 10, wherein the first distal end overlaps the source electrode.

12. The device of claim 10, wherein the P-type GaN layer has a width defined between the first edge and the second edge, wherein the second distal end extends beyond the second edge by a distance greater than 20% of the width.

13. The device of claim 10, wherein the P-type GaN layer has a width defined between the first edge and the second edge, wherein the second distal end extends beyond the second edge by a distance greater than 30% of the width.

14. The device of claim 10, wherein the P-type GaN layer has a width defined between the first edge and the second edge, wherein the second distal end extends beyond the second edge by a distance greater than 50% of the width.

35. A method of forming a device, the method comprising:
providing a silicon layer;
forming a gallium nitride (GaN)-based layer on the silicon layer;
forming a source region on the GaN-based layer and having a source electrode;
forming a drain region on the GaN-based layer and separate from the source region;
forming a gate region between the source region and the drain region, the gate region including a P-type GaN layer having a first thickness and disposed on the GaN-based layer; and
forming a dielectric layer disposed on the GaN-based layer and having a second thickness that is less the first thickness, wherein the dielectric layer is in contact with the P-type GaN layer.

16. The method of claim 15, further comprising forming a field plate disposed on the dielectric layer and positioned between the P-type GaN layer and the drain region, wherein the field plate is connected to the source electrode.

17. The method of claim 16, further comprising forming a shield layer extending from the P-type GaN layer towards the drain region and extending over at least a portion of the field plate.

18. The method of claim 17, wherein the dielectric layer is a first dielectric layer, and wherein the method further comprises forming a second dielectric layer disposed between the field plate and the first dielectric layer.

19. The method of claim 18, further comprising forming a third dielectric layer disposed on the field plate.

20. The method of claim 19, further comprising forming a fourth dielectric layer disposed on the third dielectric layer.
